(19) United States
(12) Patent Application Publication
(10) Pub. No.: US 2020/0294873 A1
(43) Pub. Date: Sep. 17, 2020

(54) SEMICONDUCTOR DEVICE

(71) Applicants: KABUSHIKI KAISHA TOSHIBA, Minato-ku (JP); TOSHIBA ELECTRONIC DEVICES & STORAGE CORPORATION, Minato-ku (JP)

(72) Inventor: Ryohei GEJO, Kanazawa (JP)

(73) Assignees: KABUSHIKI KAISHA TOSHIBA, Minato-ku (JP); TOSHIBA ELECTRONIC DEVICES & STORAGE CORPORATION, Minato-ku (JP)

(21) Appl. No.: 16/434,349

(22) Filed: Jun. 7, 2019

(30) Foreign Application Priority Data
Mar. 11, 2019 (JP) 2019-044004

(51) Int. Cl. H01L 23/051

(52) U.S. Cl. CPC H01L 23/051; H01L 27/0727

(57) ABSTRACT

A semiconductor device includes upper and lower electrode plates, and semiconductor elements therebetween. First and second metal plates are disposed between the upper electrode plate and a first semiconductor element, and between the upper electrode plate and a second semiconductor element, respectively. The first semiconductor element is disposed between central portions of the upper and lower electrode plates. The upper electrode plate includes a first upper pole electrically connected to the first semiconductor element and a second upper pole electrically connected to the second semiconductor element. A first total length is a sum of a height of the first upper pole and thicknesses of the first semiconductor element and the first metal plate. A second total length longer than the first total length is a sum of a height of the second upper pole and thicknesses of the second semiconductor element and the second metal plate.

### CROSS-REFERENCE TO RELATED APPLICATIONS

This application is based upon and claims the benefit of priority from Japanese Patent Application No. 2019-044004, filed on Mar. 11, 2019; the entire contents of which are incorporated herein by reference.

### FIELD

Embodiments relate to a semiconductor device.

### BACKGROUND

Semiconductor devices for power control may include semiconductor elements such as MOSFETs, IGBTs (Insulated Gate Bipolar Transistors), diodes, etc., disposed in parallel between two electrode plates. For example, the semiconductor elements are pressed in contact with the two electrode plates and are electrically connected to the two electrode plates to perform a switching control of a large current flowing between the two electrode plates. However, when the heat dissipation under the high-temperature operation becomes nonuniform between the two electrode plates, the pressure that is applied to the semiconductor elements becomes nonuniform due to the thermal expansion difference inside the respective electrode plates. Thus, the semiconductor elements may be broken under the high-temperature operation; and the reliability decreases in the semiconductor device.

### BRIEF DESCRIPTION OF THE DRAWINGS

FIGS. 1A and 1B are schematic views showing a semiconductor device according to an embodiment;

FIG. 2 is a schematic view showing components of the semiconductor device according to the embodiment;

FIG. 3 is a schematic view showing a semiconductor device according to a comparative example;

FIG. 4 is a schematic view showing components of a semiconductor device according to a modification of the embodiment;

FIG. 5 is a schematic view showing components of a semiconductor device according to other modification of the embodiment;

FIGS. 6A and 6B are schematic views showing components of semiconductor devices according to yet other modifications of the embodiment; and

FIG. 7 is a schematic view showing a semiconductor device according to a modification of the embodiment.

### DETAILED DESCRIPTION

According to an embodiment, a semiconductor device includes an upper electrode plate, a lower electrode plate opposing the upper electrode plate, a plurality of semiconductor elements disposed between the upper electrode plate and the lower electrode plate, and a plurality of metal plates disposed respectively between the upper electrode plate and the plurality of semiconductor elements. The plurality of semiconductor elements are connected in parallel between the upper electrode plate and the lower electrode plate. The upper electrode plate includes a plurality of upper poles on the lower electrode plate side, the plurality of upper poles being electrically connected to the plurality of semiconductor elements, respectively, via the plurality of metal plates. The plurality of semiconductor elements includes a first semiconductor element and a second semiconductor element. The first semiconductor element is disposed between a central portion of the upper electrode plate and a central portion of the lower electrode plate. The second semiconductor element is disposed further outward than the first semiconductor element. The plurality of metal plates include a first metal plate and a second metal plate, the first metal plate being disposed between the upper electrode plate and the first semiconductor element, the second metal plate being disposed between the upper electrode plate and the second semiconductor element. The plurality of upper poles include a first upper pole electrically connected to the first semiconductor element with the first metal plate interposed and second upper pole electrically connected to the second semiconductor element with the second metal plate interposed. The first upper pole has a first height along the first direction directed from the upper electrode plate toward the lower electrode plate. The second upper pole has a second height along the first direction. The first semiconductor element and the first metal plate each have a thickness along the first direction. A first total length is a sum of the thickness of the first semiconductor element, the thickness of the first metal plate and the first height of the first upper pole. The second semiconductor element and the second metal plate each have a thickness along the first direction. A second total length is a sum of the thickness of the second semiconductor element, the thickness of the second metal plate, and the second height of the second upper pole. The second total length is longer than the first total length.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

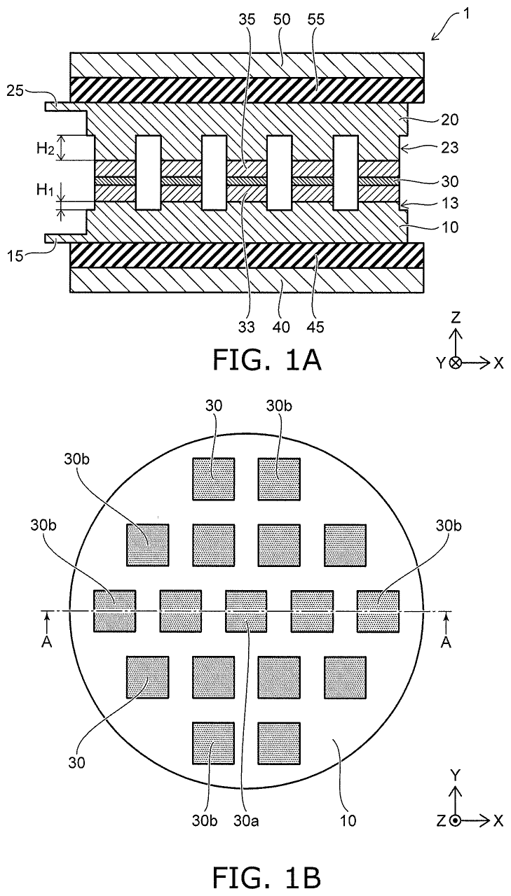

FIGS. 1A and 1B are schematic views showing a semiconductor device 1 according to an embodiment. FIG. 1A is a schematic cross-sectional view; and FIG. 1B is a schematic plan view. FIG. 1A is a schematic view illustrating a cross section along line A-A shown in FIG. 1B.

As shown in FIG. 1A, the semiconductor device 1 includes an electrode plate 10, an electrode plate 20, and multiple semiconductor elements 30. The semiconductor elements 30 are disposed between the electrode plate 10 and the electrode plate 20 and electrically connected in parallel between the electrode plate 10 and the electrode plate 20.

The electrode plate 10 and the electrode plate 20 include, for example, a material having a low electrical resistivity and a high thermal conductivity such as copper, aluminum, etc. The multiple semiconductor elements 30 include, for example, IGBTs and diodes.

The semiconductor device 1 further includes metal plates 33, metal plates 35, a pressure plate 40, a pressure plate 50, an insulating plate 45, and an insulating plate 55. The electrode plate 10 and the electrode plate 20 are disposed between the pressure plate 40 and the pressure plate 50. The insulating plate 45 is disposed between the electrode plate 10 and the pressure plate 40. The insulating plate 55 is disposed between the electrode plate 20 and the pressure plate 50.

The pressure plates 40 and 50 include, for example, aluminum, iron, etc. The insulating plates 45 and 55 include, for example, a resin. The insulating plate 45 electrically insulates the pressure plate 40 from the electrode plate 10. The insulating plate 55 electrically insulates the pressure plate 50 from the electrode plate 20.

For example, the electrode plate 10 includes multiple inner poles 13; and the electrode plate 20 includes multiple inner poles 23. The semiconductor elements 30 are disposed respectively between the inner poles 13 and the inner poles 23. The metal plates 33 are disposed between the inner poles 13 and the semiconductor elements 30. The metal plates 35 are disposed between the inner poles 23 and the semiconductor elements 30.

The inner poles 13 have a height H₁ in the direction (e.g., the Z-direction) from the electrode plate 10 toward the electrode plate 20. The inner poles 23 have a height H₂ in the direction (e.g., the −Z direction) from the electrode plate 20 toward the electrode plate 10. For example, the height H₁ is lower than the height H₂.

For example, the metal plates 33 and the metal plates 35 have higher hardnesses than the hardnesses of the electrode plate 10 and the electrode plate 20. The metal plates 33 and the metal plates 35 include, for example, molybdenum.

The metal plates 33 are pressed in contact with the semiconductor elements 30 and the electrode plate 10 by pressure applied between the pressure plate 40 and the pressure plate 50. The metal plates 35 are pressed in contact with the semiconductor elements 30 and the electrode plate 20 by the pressure applied between the pressure plate 40 and the pressure plate 50. Thereby, the semiconductor elements 30 are electrically connected to the electrode plate 10 and the electrode plate 20.

The electrode plate 10 includes a connection terminal 15; and the electrode plate 20 includes a connection terminal 25. The semiconductor device 1 is configured to perform switching control of a large current supplied from the outside via the connection terminals 15 and 25 by the multiple semiconductor elements 30 connected in parallel.

FIG. 1B is a plan view illustrating the arrangement of the semiconductor elements 30 on the electrode plate 10. The multiple semiconductor elements 30 include a first semiconductor element 30a and a second semiconductor element 30b. The first semiconductor element 30a is disposed at the center of the electrode plate 10. The second semiconductor element 30b is disposed at a position most proximal to the outer edge in a direction from the center toward the outer edge of the electrode plate 10. Hereinbelow, there are cases where the first semiconductor element 30a and the second semiconductor element 30b are described by being differentiated and cases where the first semiconductor element 30a and the second semiconductor element 30b are generally called the semiconductor element 30. This is similar for the other components as well.

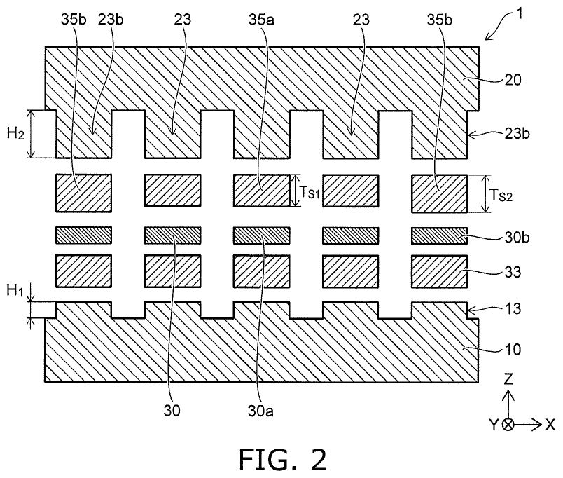

FIG. 2 is a schematic view showing components of the semiconductor device 1 according to the embodiment. FIG. 2 is a schematic view illustrating the arrangement of the electrode plate 10, the electrode plate 20, the semiconductor elements 30, the metal plates 33, and the metal plates 35 before the pressure is applied between the pressure plate 40 and the pressure plate 50.

As shown in FIG. 2, the first semiconductor element 30a is disposed between the metal plate 33 and a metal plate 35a. The metal plate 35a is one of the multiple metal plates 35. The second semiconductor element 30b is disposed between the metal plate 33 and a second metal plate 35b. The metal plate 35b is one of the multiple metal plates 35.

The thicknesses in the Z-direction of the metal plates 33 are uniform. The thicknesses in the Z-direction of the semiconductor elements 30 also are uniform. The heights H₁ and H₂ of the inner poles 13 and 23 also are uniform.

The metal plate 35a has a thickness T_{S1} in the Z-direction. The metal plate 35b has a thickness T_{S2} in the Z-direction. The metal plate 35b is provided so that the thickness T_{S2} is thicker than the thickness T_{S1}. The thicknesses in the Z-direction of the metal plates 35 that are positioned between the metal plate 35a and the metal plate 35b are, for example, the same as the thickness T_{S1}, or thicker than the thickness T_{S1} and thinner than the thickness T_{S2}.

The metal plate 35b is provided so that all of the metal plates 35 contact the inner poles 23 when the pressure is applied between the pressure plate 40 and the pressure plate 50. In other words, for example, the metal plate 35b is provided so that all of the metal plates 35 contact the inner poles 23 by a deformation of an inner pole 23b contacting the metal plate 35b. In other words, the difference between the thickness T_{S2} and the thickness T_{S1} is set not to exceed a range in which all of the metal plates 35 can contact the inner poles 23.

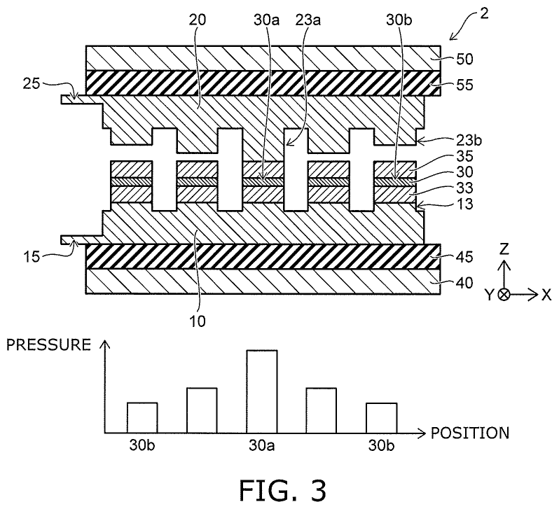

FIG. 3 is a schematic view showing a semiconductor device 2 according to a comparative example. FIG. 3 is a schematic view illustrating a cross section along line A-A shown in FIG. 1B. FIG. 3 also shows the pressure applied to the semiconductor elements 30 at a high temperature (when operating). In the semiconductor device 2, the thicknesses in the Z-direction of the metal plates 35 also are uniform. In FIG. 3, the lengths of the inner poles 23 are illustrated as being different to show the thermal expansion difference of the inner poles 23. Although the electrode plate 20 and a portion of the metal plates 35 are illustrated as being separated, neither are actually separated.

For example, in the case where the semiconductor elements 30 are disposed at high density between the electrode plate 10 and the electrode plate 20, the heat from the first semiconductor element 30a disposed at the center of the electrode plate 10 and the electrode plate 20 is not dissipated easily compared to the heat from the second semiconductor element 30b disposed outward from the first semiconductor element 30a. Accordingly, the temperature at the center of the electrode plate 10 and the electrode plate 20 is high compared to the temperature at the outer perimeter portion. Therefore, the thermal expansion at the center of the electrode plate 10 and the electrode plate 20 is larger than the thermal expansion at each of the outer perimeter portions. Accordingly, the pressure that is applied to the semiconductor elements 30 at a high temperature becomes nonuniform; for example, the pressure that is applied to the first semiconductor element 30a and the metal plate 35a becomes larger than the pressure applied to the second semiconductor element 30b and the metal plate 35b.

Also, when the high-temperature state (the ON-state) and the low-temperature state (the OFF-state) are repeated by the switching operation of the semiconductor elements 30, thermal fatigue, e.g., plastic deformation of the metal plate 35a to which the high pressure is applied at a high temperature becomes large. Thereby, the uniformity of the pressure applied to the semiconductor elements 30 may degrade; and the semiconductor elements 30 may be broken.

In the semiconductor device 1, the thickness in the Z-direction of the metal plate 35b positioned between the inner pole 23b and the second semiconductor element 30b is set to be thicker than the thickness in the Z-direction of the metal plate 35a positioned between an inner pole 23a and the first semiconductor element 30a. Thereby, the thermal expansion difference at a high temperature (when operating) is absorbed by the thickness difference of the metal plate 35a and the metal plate 35b; and the pressure can be applied uniformly to the semiconductor elements 30. As a result, for example, the plastic deformation due to the thermal fatigue of the metal plate 35a can be suppressed; and the reliability of the semiconductor device 1 can be improved.

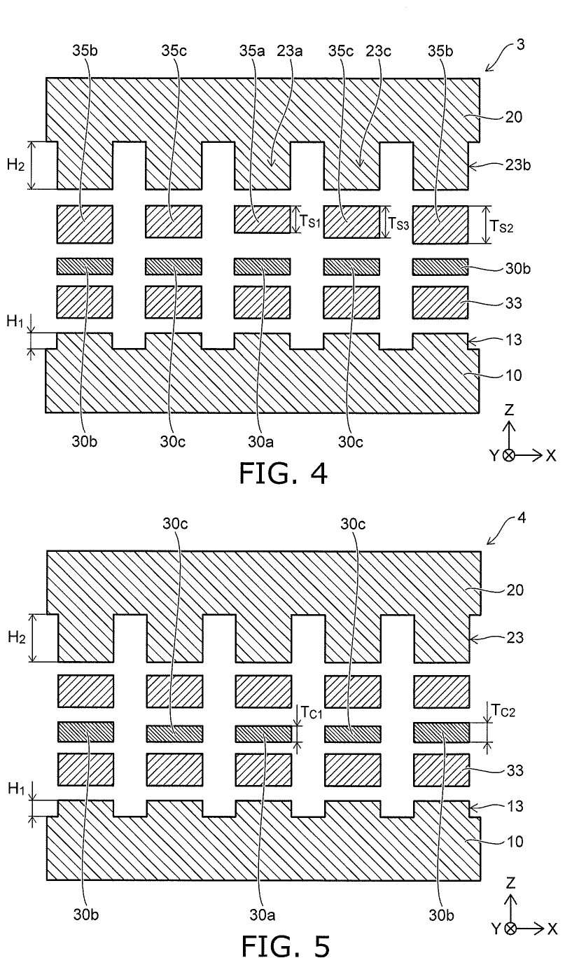

FIG. 4 is a schematic view showing components of a semiconductor device 3 according to a modification of the embodiment. FIG. 4 is a schematic view illustrating the arrangement of the electrode plate 10, the electrode plate 20, the semiconductor elements 30, the metal plates 33, and the metal plates 35 before the pressure is applied between the pressure plate 40 and the pressure plate 50.

FIG. 4 shows a third semiconductor element 30c in addition to the first semiconductor element 30a and the second semiconductor element 30b. The third semiconductor element 30c is one of the multiple semiconductor elements 30 and is disposed between the first semiconductor element 30a and the second semiconductor element 30b. The multiple metal plates 35 further include a metal plate 35c. The third semiconductor element 30c is positioned between the metal plate 33 and the metal plate 35c.

In the example as well, the thicknesses in the Z-direction of the metal plates 33 are uniform. The thicknesses in the Z-direction of the semiconductor elements 30 also are uniform. The heights H₁ and H₂ of the inner poles 13 and 23 also are uniform.

The metal plate 35a is disposed between the inner pole 23a and the first semiconductor element 30a and has the thickness T_{S1} in the Z-direction. The metal plate 35b is disposed between the inner pole 23b and the second semiconductor element 30b and has the thickness T_{S2} in the Z-direction. The metal plate 35c is disposed between an inner pole 23c and the third semiconductor element 30c and has a thickness T_{S3} in the Z-direction.

The thicknesses of the metal plates 35 have the relationship T_{S1}<T_{S3}<T_{S2}. In other words, the metal plates 35 are disposed so that the thickness in the Z-direction increases in the directions (e.g., the X-direction and the Y-direction) from the center toward the outer edge of the electrode plate 20. Thereby, it is possible to improve the uniformity of the pressure applied to the semiconductor elements 30 when operating and the reliability of the semiconductor device 3.

FIG. 5 is a schematic view showing components of a semiconductor device 4 according to other modification of the embodiment. FIG. 5 is a schematic view illustrating the arrangement of the electrode plate 10, the electrode plate 20, the semiconductor elements 30, the metal plates 33, and the metal plates 35 before the pressure is applied between the pressure plate 40 and the pressure plate 50.

In the example, the thicknesses in the Z-direction of the metal plates 33 are uniform. The thicknesses in the Z-direction of the metal plates 35 also are uniform. The heights H₁ and H₂ of the inner poles 13 and 23 also are uniform.

As shown in FIG. 5, the first semiconductor element 30a has a thickness T_{C1} in the Z-direction; and the second semiconductor element 30b has a thickness T_{C2} in the Z-direction. The second semiconductor element 30b is disposed so that T_{C2}>T_{C1}. The difference between the thickness T_{C2} and the thickness T_{C1} is set not to exceed a range in which all of the metal plates 35 can contact the inner poles 23 when the pressure is applied between the pressure plate 40 and the pressure plate 50.

The third semiconductor element 30c is disposed between the first semiconductor element 30a and the second semiconductor element 30b and has a thickness in the Z-direction that is thinner than the thickness T_{C2}. The thickness in the Z-direction of the third semiconductor element 30c may be the same as the thickness T_{C1} in the Z-direction of the first semiconductor element 30a.

In the semiconductor device 4, by disposing the second semiconductor element 30b which is thicker than the first semiconductor element 30a, it is possible to improve the uniformity of the pressure applied to the semiconductor elements 30 when operating and the reliability of the semiconductor device 4.

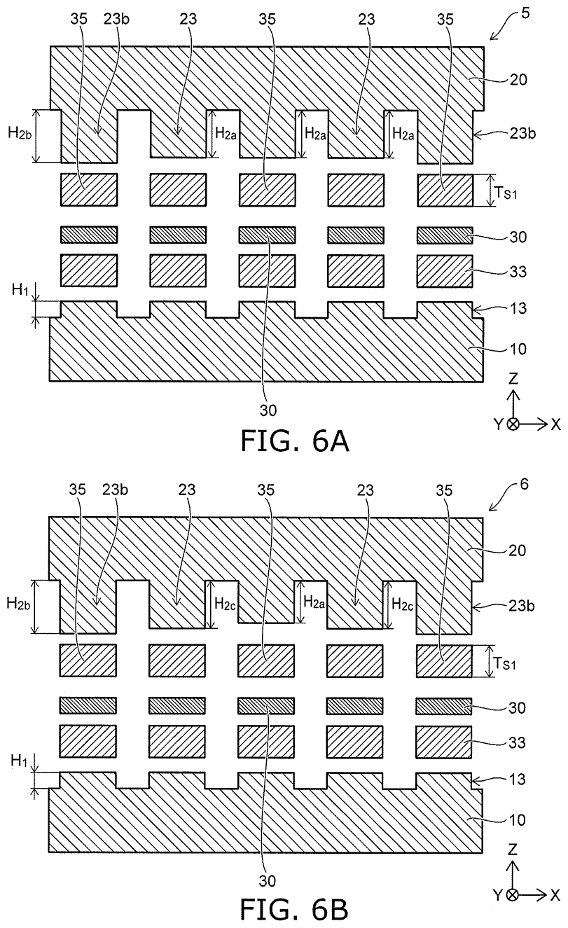

FIGS. 6A and 6B are schematic views showing components of semiconductor devices 5 and 6 according to modifications of the embodiment. FIGS. 6A and 6B are schematic views illustrating the arrangement of the electrode plate 10, the electrode plate 20, the semiconductor elements 30, the metal plates 33, and the metal plates 35 before the pressure is applied between the pressure plate 40 and the pressure plate 50.

In FIGS. 6A and 6B, the thicknesses in the Z-direction of the semiconductor elements 30 disposed between the electrode plate 10 and the electrode plate 20 are the same; and the thicknesses in the Z-direction of the metal plates 35 are the same. In the examples, the electrode plate 20 is provided so that the height H₂ in the Z-direction is different between the inner poles 23.

In the semiconductor device 5 shown in FIG. 6A, for example, the inner pole 23b disposed at a position most proximal to the outer edge of the electrode plate 20 in a direction parallel to the upper surface of the electrode plate 20 (the surface positioned on the side opposite to the surface where the inner poles 23 are disposed) has a height H_{2b} in the Z-direction. The inner poles 23 that are positioned further inward than the inner pole 23b have a height H₂ₐ in the Z-direction. In the example, the heights in the Z-direction of the inner poles 23 have the relationship H_{2b}>H₂ₐ.

In the semiconductor device 6 shown in FIG. 6B, the electrode plate 20 includes the inner pole 23a disposed at the center of the electrode plate 20, the inner pole 23b, and the inner pole 23c. The inner pole 23a is disposed at the center of the lower surface of the electrode plate 20. The inner pole 23c is positioned between the inner pole 23a and the inner pole 23b. The inner pole 23a has a height H₂ₐ in the Z-direction; and the inner pole 23c has a height H_{2c} in the Z-direction. In the example, the heights in the Z-direction of the inner poles 23 have the relationship H_{2b}>H_{2c}>H₂ₐ.

In the semiconductor devices 5 and 6, by changing the height in the Z-direction between the inner poles 23 of the electrode plate 20, it is possible to improve the uniformity of the pressure applied to the semiconductor elements 30 when operating and the reliability of the semiconductor devices 5 and 6. The embodiment is not limited to the examples; and the heights of the inner poles 13 provided in the electrode plate 10 may be changed.

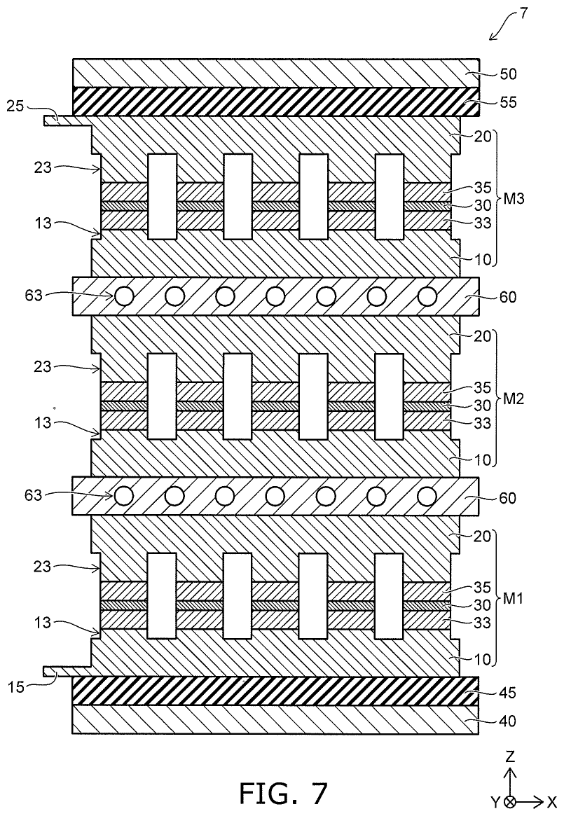

FIG. 7 is a schematic view showing a semiconductor device 7 according to a modification of the embodiment. The semiconductor device 7 has a configuration in which multiple semiconductor modules M1 to M3 are stacked between the pressure plate 40 and the pressure plate 50. A large-current switching control under high voltage can be performed in the semiconductor device 7.

The semiconductor modules M1 to M3 each include the electrode plate 10, the electrode plate 20, the semiconductor elements 30, the metal plates 33, and the second metal plates 35. The semiconductor modules M1 to M3 are stacked with cooling plates 60 interposed. For example, the material of the cooling plate 60 is aluminum; and the cooling plate 60 includes a flow channel 63 through which a cooling medium circulates.

The semiconductor modules M1 to M3 each include the metal plate 35a, the metal plate 35b, and the metal plate 35c. The metal plate 35a has the thickness T_{S1} in the Z-direction; and the metal plate 35b has the thickness T_{S2} in the Z-direction. The metal plate 35c has the thickness T_{S3} in the Z-direction (referring to FIG. 4). The thicknesses of the metal plates 35 have the relationships T_{S1} and T_{S3}<T_{S2}.

Alternately, the semiconductor modules M1 to M3 include the first semiconductor element 30a, the second semiconductor element 30b, and the third semiconductor element 30c (referring to FIG. 5) and may be configured so that the thickness T_{C2} in the Z-direction of the second semiconductor element 30b is thicker than the thickness T_{C1} in the Z-direction of the first semiconductor element 30a and a thickness T_{C3} in the Z-direction of the third semiconductor element 30c.

Thereby, the pressure that is applied to the semiconductor elements 30 when operating may have higher uniformity; and the reliability of the semiconductor device 7 can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
an upper electrode plate;
a lower electrode plate opposing the upper electrode plate;
a plurality of semiconductor elements disposed between the upper electrode plate and the lower electrode plate, the plurality of semiconductor elements being connected in parallel between the upper electrode plate and the lower electrode plate; and
a plurality of metal plates disposed respectively between the upper electrode plate and the plurality of semiconductor elements,
the upper electrode plate including a plurality of upper poles on the lower electrode plate side, the plurality of upper poles being electrically connected to the plurality of semiconductor elements, respectively, via the plurality of metal plates,
the plurality of semiconductor elements including a first semiconductor element and a second semiconductor element,
the first semiconductor element being disposed between a central portion of the upper electrode plate and a central portion of the lower electrode plate,
the second semiconductor element being disposed further outward than the first semiconductor element,
the plurality of metal plates including a first metal plate and a second metal plate, the first metal plate being disposed between the upper electrode plate and the first semiconductor element, the second metal plate being disposed between the upper electrode plate and the second semiconductor element,
the plurality of upper poles including a first upper pole electrically connected to the first semiconductor element with the first metal plate interposed and a second upper pole electrically connected to the second semiconductor element with the second metal plate interposed, the first upper pole having a first height along a first direction directed from the upper electrode plate toward the lower electrode plate, the second upper pole having a second height along the first direction,
the first semiconductor element and the first metal plate each having a thickness along the first direction, a first total length being a sum of the thickness of the first semiconductor element, the thickness of the first metal plate and the first height of the first upper pole,
the second semiconductor element and the second metal plate each having a thickness along the first direction, a second total length being a sum of the thickness of the second semiconductor element, the thickness of the second metal plate, and the second height of the second upper pole, the second total length being longer than the first total length.

2. The device according to claim 1, wherein
the plurality of upper poles have the same height;
the first semiconductor element has the thickness same as the thickness of the second semiconductor element; and
the second metal plate has the thickness thicker than the thickness of first metal plate.

3. The device according to claim 2, further comprising other metal plates disposed between the lower electrode plate and the plurality of semiconductor elements,
the lower electrode plate including a plurality of lower poles electrically connected respectively to the plurality of semiconductor elements via the other metal plates.

4. The device according to claim 1, wherein the plurality of metal plates includes a material having a higher hardness than a hardness of a material of the upper electrode plate.

5. The device according to claim 1, wherein the upper electrode plate includes copper or aluminum, and the plurality of metal plates includes molybdenum.

6. The device according to claim 2, wherein
the upper electrode plate has a first surface and a second surface opposite to the first surface, the plurality of semiconductor elements being positioned on the first surface side of the upper electrode plate;
the plurality of semiconductor elements further includes a third semiconductor element, the third semiconductor element being positioned between the first semiconductor element and the second semiconductor element, the third semiconductor element having a thickness same as the thicknesses of the first and second semiconductor elements, the first to third semiconductor elements being arranged in a second direction along the second surface of the upper electrode plate, the second direction being directed from the center portion of the upper electrode plate to an outer edge of the upper electrode plate; and
the plurality of metal plates includes a third metal plate positioned between the upper electrode plate and the third semiconductor element, the third metal plate having a thickness along the first direction thinner than the thickness of the second metal plate, the thickness of the third metal plate being same as or thicker than the thickness of the first metal plate.

7. The device according to claim 1, wherein
the plurality of upper poles have the same height;
the first metal plate has the thickness same as the thickness of the second metal plate; and
the second semiconductor element has the thickness thicker than the thickness of the first semiconductor element.

8. The device according to claim 7, wherein
the upper electrode plate has a first surface and a second surface opposite to the first surface, the plurality of semiconductor elements being positioned on the first surface side of the upper electrode plate,
the plurality of semiconductor elements further including a third semiconductor element positioned between the first semiconductor element and the second semiconductor element, the first to third semiconductor element being arranged in a second direction along the second surface of the upper electrode plate, the second direction being directed from the center portion of the upper electrode plate toward an outer edge of the upper electrode plate,
the plurality of metal plates further includes a third metal plate, the third metal plate having a thickness along the first direction same as the thicknesses of the first and second metal plates,
the plurality of upper poles includes a third upper pole, the third metal plate being positioned between the third upper pole and the third semiconductor element, and
the third semiconductor element having a thickness in the first direction thinner than the thickness of the second semiconductor element, the thickness of the third semiconductor element being same as or thicker than the thickness of the first semiconductor element.

9. The device according to claim 1, wherein
the first semiconductor element has the thickness same as the thickness of the second semiconductor element;
the first metal plate has the thickness same as the thickness of the second metal plate; and
the second height of the second upper pole being larger than the first height of the first upper pole.

10. The device according to claim 9, wherein
the upper electrode plate has a first surface and a second surface opposite to the first surface, the plurality of semiconductor elements being positioned on the first surface side of the upper electrode plate;
the plurality of upper poles further includes a third upper pole positioned between the first upper pole and the second upper pole, the first to third upper poles being arranged in a second direction along the second surface of the upper electrode plate, the second direction being directed from the center portion of the upper electrode plate to an outer edge of the upper electrode plate;
the third upper pole having a third height along the first direction lower than the second height of the second upper pole, the third height being same as or higher than the first height of the first upper pole,
the plurality of semiconductor element further including a third semiconductor element positioned between the lower electrode plate and the third upper pole, the third semiconductor element having a thickness same as the thicknesses of the first and second semiconductor elements, and
the plurality of metal plates further includes a third metal plate positioned between the third semiconductor element and the third upper pole, the third metal plate having a thickness along the first direction same as the thicknesses of the first and second metal plates.
